(19) United States
(12) Patent Application Publication
(10) Pub. No.: US 2026/0026367 A1
(43) Pub. Date: Jan. 22, 2026

(54) SEMICONDUCTOR PACKAGE AND METHOD OF MANUFACTURING THE SAME

(71) Applicant: Samsung Electronics Co., Ltd., Suwon-si (KR)

(72) Inventor: Woojae KIM, Suwon-si (KR)

(21) Appl. No.: 19/050,176

(22) Filed: Feb. 11, 2025

(30) Foreign Application Priority Data
Jul. 18, 2024 (KR) 10-2024-0095019

(51) Int. Cl. H01L 23/495; H01L 21/48; H01L 23/00; H01L 23/31

(52) U.S. Cl. CPC H01L 23/4952; H01L 21/4825; H01L 23/3128; H01L 23/49582; H01L 24/16; H01L 2224/16245

(57) ABSTRACT

A semiconductor package including a first lead comprising a first surface and a second surface that is opposite to the first surface, at least one semiconductor chip that is placed on the first surface of the first lead, a connecting structure body that is connected to the first lead, and a molding layer configured to cover the first lead and the semiconductor chip. The first lead comprises a recess that is formed on the second surface of the lead, and the connecting structure body is placed in the recess. The semiconductor chip, the first lead, and the connecting structure body are electrically connected to each other.

### CROSS-REFERENCE TO RELATED APPLICATION(S)

This application claims the benefit of Korean Patent Application No. 10-2024-0095019, filed on Jul. 18, 2024, in the Korean Intellectual Property Office, the disclosure of which is incorporated herein by reference.

### BACKGROUND

Example embodiments relate to a semiconductor package and a method of manufacturing the semiconductor package.

Due to the development of the electronics industry, as demands for higher functionality, higher speed, and smaller size of electronic components increase, the integration level of semiconductor chips is increasing. In response to the trend toward high integration of semiconductor chips, research and development on semiconductor chips with fine patterns and a semiconductor package containing the semiconductor chips are continuously being conducted. Various semiconductor packages have been proposed to achieve high integration and miniaturization. A semiconductor package that electrically connects leads and semiconductor chips and covers the leads and semiconductor chips with a molding layer can be solder attached to a package substrate, such as a lead or a printed circuit board (PCB). Since one side of the lead facing the package substrate has a generally flat shape, cracks occur at the solder attached area, and thus the reliability of the semiconductor package is reduced.

### SUMMARY

The present application discloses a semiconductor package with improved durability, and a method of manufacturing the same.

The present application further discloses a semiconductor package that may be firmly mounted on a package substrate, and a method of manufacturing the same.

The technical tasks to be achieved by the present example embodiments are not limited to the technical tasks described above, and other technical tasks not described will be apparent to those skilled in the art from the present specification and the accompanying drawings.

According to an aspect, there is provided a semiconductor package including first lead including a first surface and a second surface that is opposite to the first surface, at least one semiconductor chip that is placed on the first surface of the first lead, a connecting structure body that is connected to the first lead, and a molding layer configured to cover the first lead and the semiconductor chip, wherein the first lead includes a recess that is formed on the second surface of the first lead, the connecting structure body is placed in the recess, and the semiconductor chip, the first lead, and the connecting structure body are electrically connected to each other.

According to another aspect, there is provided a semiconductor package including a lead including a first surface and a second surface that is opposite to the first surface, and including a recess formed on the second surface, a semiconductor chip that is mounted on the lead by a bump connected to the first surface, and a connecting structure body that is connected with the second surface, wherein the recess is formed toward the first surface from the second surface, the connecting structure body is placed in the recess, and the semiconductor chip, the lead, and the connecting structure body are electrically connected to each other.

According to another aspect, there is provided a semiconductor package including a first lead and a second lead each including a first surface and a second surface comprising a recess, the first lead and the second lead are spaced apart from each other, a semiconductor chip mounted on both the first surface of the first lead and the first surface of the second lead, a first bump disposed between and connected to the semiconductor chip and the first surface of the first lead and a second bump disposed between and connected to the semiconductor chip and the first surface of the second lead, a plating layer, comprising tin (Sn), conformally disposed on the second surface and recess of each of the first lead and the second lead, a first connecting structure body comprising tin (Sn) and bismuth (Bi), a portion of the first connecting structure body disposed in the recess of the first lead and is connected to and in contact with the plating layer, a second connecting structure body comprising tin (Sn) and bismuth (Bi), a portion of the second connecting structure body disposed in the recess of the second lead and is connected to and in contact with the plating layer, and a molding layer covering the first lead, the second lead, the semiconductor chip, the first bump, and the second bump.

Additional aspects of example embodiments will be set forth in part in the description which follows and, in part, will be apparent from the description, or may be learned by practice of the disclosure.

According to example embodiments, it is possible to increase the attaching area of the connecting structure body to the lead.

According to example embodiments, it is possible to improve the phenomenon in which cracks occur due to the connecting structure body between the package substrate and the semiconductor package mounted on it.

The effect of the example embodiments are not limited to the above-described effects, and other effects not described would be clearly understood by those skilled in the art from the description of the claims.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is a perspective view schematically showing a semiconductor package according to an example embodiment;

FIG. 2 is a bottom view schematically showing the semiconductor package as seen from direction I of FIG. 1;

FIG. 3 is a drawing schematically showing a cross-section cut along line II-II′ of FIG. 2;

FIG. 4 is a cross-sectional view schematically showing the semiconductor package of FIG. 2 mounted on a package substrate;

FIG. 5 is a flow chart showing a method for manufacturing the semiconductor package of FIG. 1;

FIGS. 6 to 10 are intermediate stage drawings for explaining the manufacturing method of FIG. 5;

FIG. 11 is a bottom view schematically showing a semiconductor package according to an example embodiment;

FIG. 12 is a drawing schematically showing a cross-section cut along line III-III′ of FIG. 11;

FIG. 13 is a cross-sectional view schematically showing a semiconductor package according to an example embodiment;

FIG. 14 is a bottom view schematically showing a semiconductor package according to an example embodiment;

FIG. 15 is a drawing schematically showing a cross-section cut along line IV-IV′ of FIG. 14;

FIG. 16 is a perspective view schematically showing a semiconductor package according to an example embodiment; and

FIG. 17 is a drawing schematically showing a cross-section cut along line V-V′ of FIG. 16.

### DETAILED DESCRIPTION

Example embodiments of the present disclosure described below can be modified and implemented in various forms. The technical idea of the present disclosure is not limited to the example embodiments described below. With regard to the terms used in the example embodiments of the present disclosure, except for the cases where the applicant arbitrarily selected and described in detail the meaning thereof in the present disclosure, the currently widely used general terms are selected as much as possible while taking into account the function in the present disclosure. However, terms may vary depending on the intention of a person skilled in the art to which the present disclosure pertains, case law, or the emergence of new technologies. Further, terms and words used in the present disclosure and claims should not be construed as limited to their ordinary or dictionary meanings, and the terms and words should be interpreted to include meanings and concepts consistent with the technical idea of the present disclosure.

In the present disclosure, the terms “comprise,” “include” or “have,” unless otherwise specifically stated, should be understood as meaning that it may include other components, rather than excluding other components. Specifically, it will be further understood that the terms “comprise,” “include” or “have” when used herein, specify the presence of stated features, integers, steps, operations, elements, and/or components, but do not preclude the presence or addition of one or more other features, integers, steps, operations, elements, components, and/or groups thereof.

In the following description, singular expressions include plural expressions unless the context clearly dictates otherwise. Further, terms “first,” “second” and so on may be used to describe various components. However, the components are not limited by the terms, and the terms may be used for the purpose of distinguishing one component from another. Within the scope of the technical idea of the present disclosure, the first component may be named as the second component. Similarly, the second component may also be named the first component. Further, the shape and size of components may be exaggerated to emphasize clear explanation. Further, in the following description, expressions such as an upper side, top, a lower side, bottom, a side, front and a back side are expressed based on the direction shown in the drawing. If the direction of the object changes, it may be expressed differently.

Hereinafter, example embodiments of the present invention are described in detail with reference to the attached drawings so that a person having ordinary skill in the art to which the present invention pertains can easily practice the present disclosure.

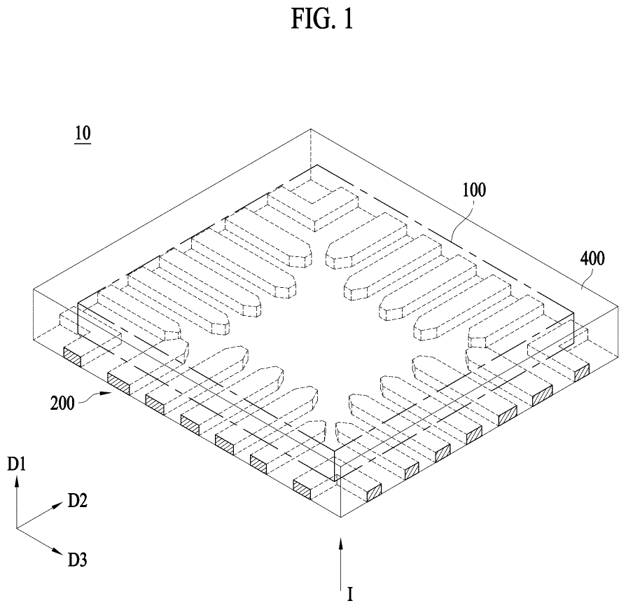

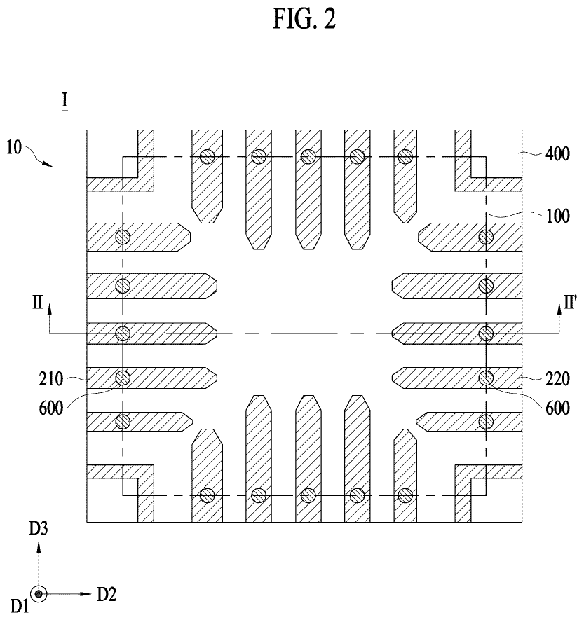

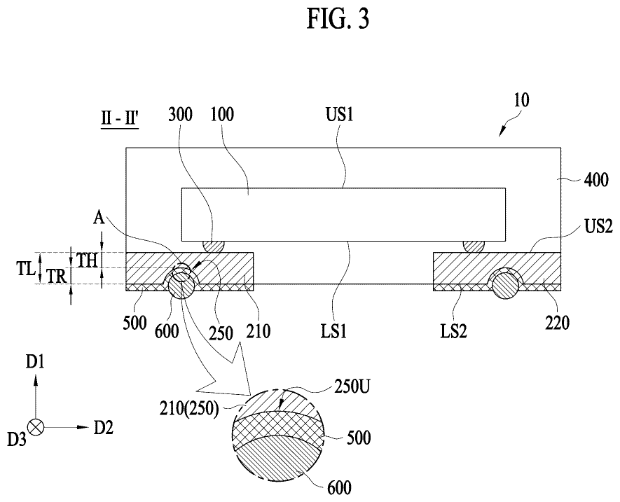

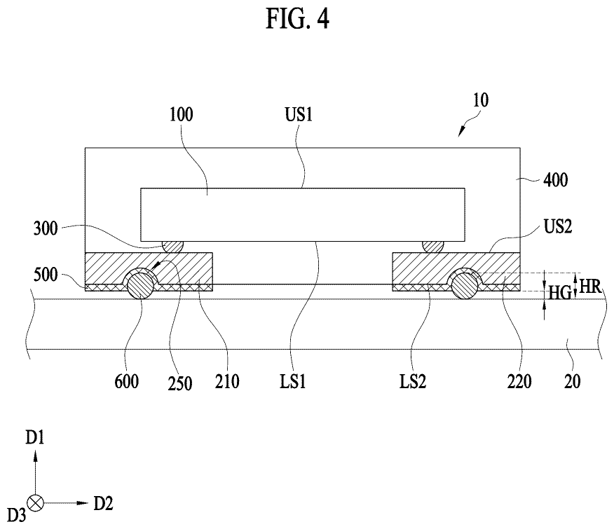

FIG. 1 is a perspective view schematically showing a semiconductor package according to an example embodiment. FIG. 2 is a bottom view schematically showing the semiconductor package as seen from direction I of FIG. 1. FIG. 3 is a drawing schematically showing a cross-section cut along line II-II′ of FIG. 2. FIG. 4 is a cross-sectional view schematically showing the semiconductor package of FIG. 2 mounted on a package substrate. In FIG. 2, the illustration of a plating layer 500 described later is omitted to aid understanding.

Referring to FIGS. 1 to 4, in some example embodiments, a semiconductor package 10 may be mounted on a package substrate 20. In some example embodiments, the package substrate 20 may include a PCB or a ceramic substrate. However, the present disclosure is not limited thereto, and it is apparent that the package substrate 20 on which the semiconductor package 10 is mounted may be a wiring substrate for a wafer level package (WLP) manufactured at the wafer level. If the package substrate 20 is a PCB, the package substrate 20 may include at least one material selected from tetrafunctional epoxy, polyphenylene ether, epoxy/polyphenylene oxide, bismaleimide triazine (BT), thermount, cyanate ester and liquid crystal polymer. Further, the package substrate 20 may include a resin impregnated in a core material such as glass fiber (glass cloth and glass fabric) together with an inorganic filler, for example, Prepreg, an Ajinomoto build-up film (ABF), or FR-4, and bismaleimide triazine (BT). However, the package substrate 20 is not limited thereto, and it is apparent that the package substrate 20 may include various types of substrates.

In some example embodiments, the semiconductor package 10 may include a semiconductor chip 100, a lead frame 200, a molding layer 400, and a connecting structure body 600. According to some example embodiments, the semiconductor package 10 may be a package in which the semiconductor chip 100 is connected to the lead frame 200, and the semiconductor chip 100 and the lead frame 200 are covered by the molding layer 400. For example, the semiconductor package 10 may be a Flip chip-Quad Flat No-lead (FC-QFN) package in which the semiconductor chip 100 is mounted in a flip-chip form on the lead frame 200. However, the semiconductor package 10 is not limited thereto, and may include various types of packages in which semiconductor chips are mounted on Quad Flat No-lead (QFN) packages or lead frames.

Hereinafter, the direction in which the semiconductor chip 100 and the lead frame 200 are arranged is defined as the first direction D1, and when viewing the semiconductor package 10 from the side, the direction perpendicular to the first direction D1 is defined as the second direction D2. Further, the direction perpendicular to the plane containing both the first direction D1 and the second direction D2 is defined as the third direction D3. For example, the first direction D1 may be a direction perpendicular to the ground, and when viewed in a plan view (e.g., as seen from direction I), the semiconductor package 10 may extend in the second direction D2 and the third direction D3.

In some example embodiments, the semiconductor package 10 may generally have a hexahedral shape, and the bottom surface of the semiconductor package 10 may be a mounting surface mounted on the package substrate 20. However, the above described example embodiments are not limiting the present disclosure, and it is apparent that the semiconductor package 10 may be transformed into various shapes. For example, FIG. 2 illustrates that the bottom surface of the semiconductor package 10 is square, but the bottom surface of the semiconductor package 10 may be rectangular.

According to example embodiments, the semiconductor chip 100 may include a logic chip or a memory chip. Specifically, the logic chip may include a microprocessor, analog components, or a digital signal processor. For example, the logic chip may be a microprocessor, such as a central processing unit (CPU), a graphic processing unit (GPU), or an application processor (ΔP), an analog device, or a digital signal processor. Further, the memory chips may include volatile memory chips, such as dynamic random access memory (DRAM) or static random access memory (SRAM), or may include non-volatile memory chips such as phase-change random access memory (PRAM), magnetoresistive random access memory (MRAM), ferroelectric random access memory (FeRAM), or resistive random access memory (RRAM). However, the semiconductor chip 100 is not limited thereto. The semiconductor chip 100 may include a system on a chip (SOC) that integrates all essential elements of a system into a single chip such as an image chip including a CCD image sensor or a CMOS image sensor, a microprocessor, memory, input/output interface, and so on. Further, according to some example embodiments, a plurality of semiconductor chips 100 may be provided, and may be disposed in a stack structure in which the plurality of semiconductor chips 100 are stacked in a flip chip form.

In some example embodiments, the semiconductor chip 100 may include a substrate and an interconnection structure. In some example embodiments, the substrate of the semiconductor chip 100 may be located on the upper portion of the semiconductor chip 100, and the interconnection structure of the semiconductor chip 100 may be located in the lower portion of the semiconductor chip 100. The substrate of the semiconductor chip 100 may include silicon (Si), for example, crystalline silicon, polycrystalline silicon, or amorphous silicon. Optionally, the substrate of the semiconductor chip 100 may include a semiconductor element such as germanium (Ge), or a compound semiconductor such as silicon carbide (SiC), gallium arsenide (GaAs), indium arsenide (InAs), and indium phosphide (InP). Meanwhile, the substrate of the semiconductor chip 100 may have a SOI (silicon on insulator) structure. The substrate of the semiconductor chip 100 may include a conductive region, for example, a doped well or a doped structure. Further, the substrate of the semiconductor chip 100 may have various device isolation structures, such as a shallow trench isolation (STI) structure. The interconnection structure of the semiconductor chip 100 may be formed on the substrate of the semiconductor chip 100. The interconnection structure of the semiconductor chip 100 may include a wiring pattern forming multiple layers, a wiring via vertically connecting the writing patterns of the multilayer structure, and an insulating layer for insulating the wiring patterns and wiring vias of the multilayer structure. The insulating layer may have a single-layer or multi-layer structure. The wiring pattern and the wiring via may include conductive materials.

In some example embodiments, the semiconductor chip 100 may include at least one circuit element. The circuit elements of the semiconductor chip 100 may be electrically connected to the external package substrate 20 through the leads (a first lead 210 and a second lead 220) of the lead frame 200 described later, and exchange electrical signals with the wiring circuits (not illustrated) formed within the package substrate 20.

According to some example embodiments, the semiconductor chip 100 may have a first surface US1 and a second surface LS1. The first surface US1 and the second surface LS1 may be opposite surfaces. For example, the first surface US1 may be the top surface of the semiconductor chip 100, and the second surface LS1 may be the lower surface of the semiconductor chip 100. Further, the second surface LS1 may be a surface (active surface) adjacent to an area where the interconnection structure and/or circuit elements of the semiconductor chip 100 are formed. In some example embodiments, at least one bump 300 may be placed on the second surface LS1 of the semiconductor chip 100. For example, the bump 300 may be placed between the semiconductor chip 100 and the lead frame 200. Even though not illustrated, a conductive connection pad (not illustrated) may be placed on the second surface LS1 of the semiconductor chip 100, and the bump 300 may be attached to a connection pad (not illustrated). According to some example embodiments, the bump 300 may contain conductive materials. For example, the bump 300 may contain at least one of copper (Cu), aluminum (Al), tin (Sn), indium (In), lead (Pb), zinc (Zn), nickel (Ni), gold (Au), silver (Ag), and combinations thereof. However, the technical idea of the present disclosure is not limited thereto. Further, in some example embodiments, the bump 300 may be, but is not limited to, a solder bump. For example, the bump 300 may have various shapes such as land, ball, pin, pillar, and so on. The number, spacing, and arrangement of bumps 300 are not limited by what is illustrated, and it is apparent that the number, spacing, and arrangement of the bumps 300 vary depending on the design.

According to some example embodiments, the lead frame 200 may be positioned so as to be exposed at the bottom surface of the semiconductor package 10. As described below, at least a portion of the lead frame 200 may not be covered by the molding layer 400. Accordingly, a second surface LS2 of leads (e.g., a first lead 210 and a second lead 220), included in the lead frame 100, may be in part not covered by the molding layer 400, and thus the lead frame 200 may be exposed from the bottom surface of the semiconductor package 10. Accordingly, the lead frame 200 may be directly mounted on the package substrate 20. Further, the lead frame 200 may be placed on the bottom side of the semiconductor chip 100 in the first direction D1. According to some example embodiments, the lead frame 200 may generally be placed on the bottom side of the edge area of the semiconductor chip 100. The lead frame 200 may be placed along the edge of the semiconductor package 10. Further, the lead frame 200 may be formed from metal or metal alloy. For example, the lead frame 200 may include copper (Cu) or a copper (Cu)-based alloy material.

According to some example embodiments, the lead frame 200 may contain multiple leads. The leads may be spaced apart at regular intervals from each other so that they do not electrically short each other. FIGS. 1 and 2 illustrate that a plurality of leads are symmetrically arranged on each side of the semiconductor package 10. However, the technical ideas presented here are not limited to the arrangement. For example, unlike what is illustrated in FIGS. 1 and 2, the number, arrangement, and shape of the leads may be varied.

According to some example embodiments, the lead frame 200 may contain the first lead 210 and the second lead 220. The first lead 210 and the second lead 220 may be formed through a stamping process for punching known copper (Cu) alloy sheets, and so on, a cutting process that is for cutting a single-piece frame-shaped lead into separated individual leads, and an etching process for machining the shape of the leads.

According to some example embodiments, the first lead 210 and the second lead 220 may be formed to have a predetermined thickness. Further, the first lead 210 and the second lead 220 may generally have a rectangular shape. Specifically, the first lead 210 and the second lead 220 may each be formed with their ends angled to facilitate alignment when mounting the package substrate 20. However, the present disclosure is not limited thereto, and the shapes of the first lead 210 and the second lead 220 may be varied in various ways.

According to some example embodiments, each of the first lead 210 and the second lead 220 may have a first surface US2 and the second surface LS2. The first surface US2 of a lead (the first lead 210 and the second lead 220) and the second surface LS2 of the lead (the first lead 210 and the second lead 220) may be opposite surfaces. For example, the first surfaces US2 of the leads (the first lead 210 and the second lead 220) may be the upper surfaces of the leads (the first lead 210 and the second lead 220), and the second surfaces LS2 of the leads (the first lead 210 and the second lead 220) may be the lower surfaces of the leads (the first lead 210 and the second lead 220). Further, the first surfaces US2 and the second surfaces LS2 of the leads (the first lead 210 and the second lead 220) may be generally flat surfaces. For example, the first surfaces US2 and the second surfaces LS2 of the leads (the first lead 210 and the second lead 220) may be surfaces substantially parallel to the second direction D2 and the third direction D3. The first surfaces US2 of the leads (the first lead 210 and the second lead 220) may face the second surface LS1 of the semiconductor chip 100.

In some example embodiments, the first lead 210 and the second lead 220 may be arranged to face each other in the second direction D2. The first lead 210 and the second lead 220 may be arranged at a certain interval. For example, the first lead 210 may be placed on one side of the semiconductor chip 100, and the second lead 220 may be placed on the other side of the semiconductor chip 100. Further, the first lead 210 and the second lead 220 may be arranged to overlap with the semiconductor chip 100 in the first direction D1, respectively. For example, the first lead 210 and the second lead 220 may be arranged to overlap with the edge area of the semiconductor chip 100 in the first direction D1, respectively. Further, the first lead 210 and the second lead 220 may overlap with the bumps 300 arranged on the second surfaces LS1 of the semiconductor chip 100 in the first direction D1, respectively. The semiconductor chip 100 may be mounted on the leads (the first lead 210 and the second lead 220) by the bumps 300 arranged between the semiconductor chip 100 and the leads (the first lead 210 and the second lead 220). Specifically, the top of the bumps 300 may directly or indirectly contact the second surfaces LS1 of the semiconductor chip 100 and the bottom of the bumps 300 may directly contact the first surfaces US2 of the leads (the first lead 210 and the second lead 220), and thus the semiconductor chip 100 and the leads (the first lead 210 and the second lead 220) may be electrically connected. However, the present disclosure is not limited thereto, and the bottom of the bumps 300 may also indirectly contact the first surfaces US2 of the leads (the first lead 210 and the second lead 220) and pads (not illustrated).

The above-described first lead 210 and the second lead 220 have identical or similar structures and functions, and thus to help understanding, the following explanation focuses on the first lead 210.

According to some example embodiments, the first lead 210 may include a recess 250. Specifically, the recess 250 may be formed on the second surface LS2 of the first lead 210. The recess 250 may be a recessed portion from the second surface LS2 of the first lead 210 toward the first surface US2 of the first lead 210. For example, the recess 250 may be a recessed portion in the first direction D1 from the second surface LS2 of the first lead 210. Further, the recess 250 may be recessed between the first surface US2 and the second surface LS2 of the first lead 210. For example, a bottom surface 250U of the recess 250 may be located between the first surface US2 and the second surface LS2 of the first lead 210. For example, the height TR from the second surface LS2 of the first lead 210 to the bottom surface 250U of the recess 250 may be lower (i.e., less) than the height TL from the second surface LS2 of the first lead 210 to the first surface US2 of the first lead 210. The recess 250 formed on the second surface LS2 of the first lead 210 may not penetrate the first surface US2 of the first lead 210. Further, the height TH from the first surface US2 of the first lead 210 to the bottom surface 250U of the recess 250 may be less than the height TL from the first surface US2 of the first lead 210 to the second surface LS2 of the first lead 210. For example, the thickness from the first surface US2 of the first lead 210 to the bottom surface 250U of the recess 250 may be thinner (i.e., less) than the thickness from the first surface US2 of the first lead 210 to the second surface LS2 of the first lead 210.

According to some example embodiments, the recess 250 may have a circular cross section on the second surface LS2 of the first lead 210. For example, the recess 250 may have a generally circular cross-section when viewed from the first direction D1. Further, the diameter of the recess 250 may decrease from the second surface LS2 of the first lead 210 toward the first surface US2 of the first lead 210. For example, the recess 250 may have a generally spherical shape.

According to some example embodiments, the plating layer 500 may be formed on the surface of the first lead 210. In some example embodiments, the plating layer 500 may be formed on the second surface LS2 of the first lead 210. For example, the plating layer 500 may be formed over the entire area of the second surface LS2 of the first lead 210 which includes an area where the recess 250 is formed and an area where the recess 250 is not formed. At least a portion of the plating layer 500 may comprise tin (Sn) or a tin (Sn)-based alloy material. For example, at least a portion of the plating layer 500 may include a tin (Sn) alloy to which tin (Sn) and lead (Pb) are added in a certain ratio, a tin (Sn) alloy to which silver (Ag) is added in a certain ratio, and so on, but the plating layer 500 is not limited thereto. The second surface LS2 of the first lead 210 may be plated with tin (Sn).

According to some example embodiments, the connecting structure body 600 may be mounted by connecting to the first lead 210. According to some example embodiments, the connecting structure body 600 may be connected to the second surface LS2 of the first lead 210. Specifically, the connecting structure body 600 may be placed in the recess 250 formed in the second surface LS2 of the first lead 210. For example, as illustrated in the enlarged view of part A of FIG. 3, the upper portion of the connecting structure body 600 may be attached to the plating layer 500 formed on the recess 250. Further, in order for the semiconductor package 10 to be mounted on the package substrate 20, the lower portion of the connecting structure body 600 may be in contact with the package substrate 20. Accordingly, the semiconductor chip 100 and the first lead 210 may be electrically connected to the package substrate 20 through the connecting structure body 600. For example, the semiconductor chip 100, the first lead 210, and the connecting structure body may be electrically connected to each other.

According to some example embodiments, the connecting structure body 600 may include a solder ball, but the connecting structure body 600 is not limited thereto, and the connecting structure body 600 should be understood as a concept including known structures configured to electrically connect the package substrate 20 and the first lead 210. Further, according to some example embodiments, the connecting structure body 600 may include a conductive material. Specifically, at least a portion of the connecting structure body 600 may include an alloy material based on tin (Sn). For example, at least a portion of the connecting structure body 600 may include a tin (Sn) alloy to which bismuth (Bi) is added in a predetermined proportion. Bismuth (Bi) has a lower melting point than tin (Sn), so it may lower the overall melting point of the connecting structure body 600, and refines the organization and increases the strength of the connecting structure body 600, and thus the mechanical properties of the connecting structure body 600 may be improved. Further, the connecting structure body 600 of tin (Sn) alloy with bismuth (Bi) addition may improve wettability with the package substrate 20 to be mounted due to its lowered surface tension, and thus the connecting structure body 600 may be uniformly attached to the recess 250. In addition, it is apparent that since the connecting structure body 600 includes tin (Sn), the connecting structure body 600 may be easily attached to the plating layer 500 including tin (Sn).

Further, according to example embodiments described above, since the recess 250 formed on the first lead 210 has a generally spherical shape, the area where the plating layer 500 formed in the recess 250 and the connecting structure body 600 are attached may be significantly increased. Further, as the area where the connecting structure body 600 is attached increases significantly, the total volume of the connecting structure body 600 connected on the first lead 210 may increase. Accordingly, the connecting structure body 600 may be rigidly attached to the recess 250, and may be stably connected to the first lead 210. In addition, since a portion of the connecting structure body 600 may be inserted into the recess 250 formed on the first lead 210, the step difference by the connecting structure body 600 between the semiconductor package 10 and the package substrate 20 may be minimized. Specifically, as illustrated in FIG. 4, when the connecting structure body 600 is not attached to the recess 250 but to the lower surface of the lead (the first lead 210 or the second lead 220), the gap between the semiconductor package 10 and the package substrate 20 will be approximately equal to the height HR from top to bottom of the connecting structure body 600. However, according to some example embodiments, since the connecting structure body 600 is attached to the recess 250, the portion of the connecting structure body 600 that protrudes from the lower surface of the lead (the first lead 210 or the lead frame 200) may be minimized by approximately the depth of the recess 250, and thus a gap HG between the lower surface of the semiconductor package 10 and the upper surface of the package substrate 20 may be minimized. For example, according to some example embodiments described above, as the area where the connecting structure body 600 is attached increases and as the area occupied by the connecting structure body 600 is minimized, cracks are minimized in the connecting structure body 600 connecting the package substrate 20 and the semiconductor package 10. Therefore, the durability of the semiconductor package 10 is enhanced against heat, mechanical shock, humidity, and electrostatic discharge that occur in actual usage environments, and the reliability of the semiconductor package 10 may be improved.

According to some example embodiments, the molding layer 400 may cover the semiconductor chip 100, the lead frame 200, and the bump 300. The molding layer 400 may be formed to cover the semiconductor chip 100, the lead frame 200, and the bump 300 to a predetermined thickness. According to some example embodiments, the molding layer 400 may cover the first surface US1, the second surface LS1, and both side surfaces of the semiconductor chip 100, respectively. Further, the molding layer 400 may cover the surface of the bump 300 and the first surface US2 of the leads (the first lead 210 and the second lead 220). Further, according to some example embodiments, the molding layer 400 may cover one side where the first lead 210 and the second lead 220 face each other, and another side, which is the opposite to the one side, of the first lead 210 and the second lead 220 may not be covered. However, the molding layer 400 is not limited thereto, and the molding layer 400 may not cover the first surfaces US1 of the semiconductor chip 100. For example, the top surface of the molding layer 400 may be coplanar with the first surface US1 of the semiconductor chip 100. In this case, the first surface US1 of the semiconductor chip 100 may be exposed from the top surface of the semiconductor package 10. Further, the molding layer 400 may cover all surfaces except the second surface LS2 of the leads (the first lead 210 and the second lead 220). In some example embodiments, the molding layer 400 may be a resin including epoxy or polyimide. For example, the resin may include bisphenol-group epoxy resin, polycyclic aromatic epoxy resin, o-cresol novolac epoxy resin, biphenyl-group epoxy resin or naphthalene-group epoxy resin. In some example embodiments, the molding layer 400 may be an epoxy molding compound. However, the material of the molding layer 400 is not particularly limited to the examples described above.

In the example embodiments described above, it is described focused on the leads (the first lead 210 and the second lead 220) that are arranged to face each other in the second direction D2. However, it is apparent that even in the case of leads arranged to face each other in the third direction D3, a structure and a function identical or similar to the example embodiments described above may be applied. Further, it is described that the leads of the lead frame 200 illustrated in FIG. 1 have different lengths. However, the present disclosure is not limited thereto. For example, the leads of the lead frame 200 may have the same length.

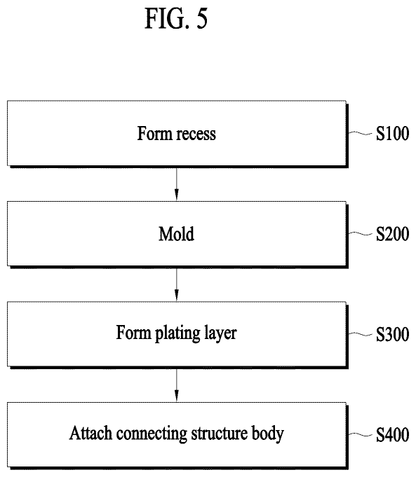

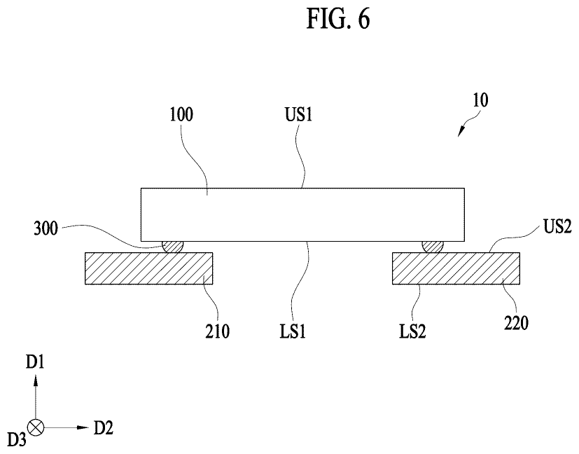

FIG. 5 is a flow chart showing a method for manufacturing the semiconductor package of FIG. 1. FIGS. 6 to 10 are intermediate stage drawings for explaining the manufacturing method of FIG. 5. Hereinafter, a method for manufacturing the semiconductor package 10 according to some example embodiments will be described with reference to FIGS. 5 to 10.

In some example embodiments, the method for manufacturing a semiconductor package may include forming a recess in operation S100, molding in operation S200, forming a plating layer in operation S300 and attaching the connecting structure body in operation S400. According to some example embodiments, forming recess in operation S100, molding in operation S200, forming a plating layer in operation S300 and attaching the connecting structure body in operation S400 may be performed in a time series order.

Referring to FIG. 6, according to some example embodiments, in order to form a recess in operation S100, the semiconductor chip 100 mounted on the leads (the first lead 210 and the second lead 220) may be prepared. Specifically, the semiconductor chip 100 may be mounted on the leads (the first lead 210 and the second lead 220) by the bumps 300 arranged on the second surface LS1 of the semiconductor chip 100. Accordingly, each of the leads (the first lead 210 and the second lead 220) may support the semiconductor chip 100, and the leads (the first lead 210 and the second lead 220) and the semiconductor chip 100 may be electrically connected by the bump 300. Here, the leads (the first lead 210 and the second lead 220) may be leads that are separated individually through the cutting process and the etching process for processing the shape.

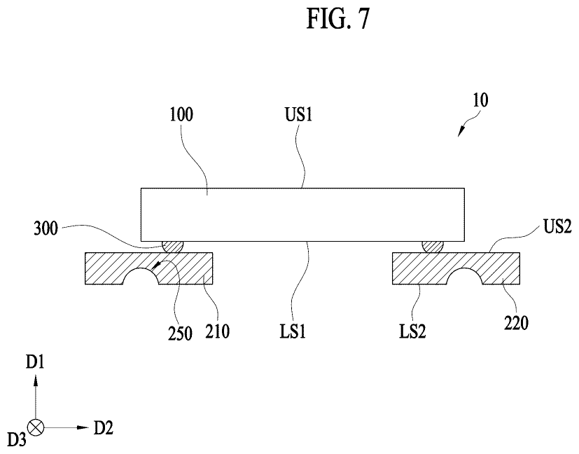

In some example embodiments, in operation S100 where the recess is formed, the recess 250 may be formed on the second surface LS2 of each of the leads (the first lead 210 and the second lead 220). For example, the recess 250 may be formed by etching the leads (the first lead 210 and the second lead 220). In some example embodiments, in operation S100 where the recess is formed, an etching process may be performed in which only the second surfaces LS2 of the leads (the first lead 210 and the second lead 220) are exposed to an etchant, or an etching process may be performed in which the second surface LS2 of the leads (the first lead 210 and the second lead 220) are exposed to plasma generated by exciting an etching gas. Specifically, in operation S100 where the recess is formed, among all surfaces of the semiconductor chip 100, the first surface US2 and the sides of each of the first lead 210 and the second lead 220, and the second surfaces LS2 of the leads (the first lead 210 and the second lead 220), except areas where the recess 250 will be formed on, may be protected with a mask layer. Further, by etching the areas where the recess 250 will be formed on the second surfaces LS2 of the leads (the first lead 210 and the second lead 220), as illustrated in FIG. 7, the recess 250 may be formed on the second surfaces LS2 of the leads (the first lead 210 and the second lead 220). Once the recess 250 is formed, the mask layer formed on the semiconductor chip 100 and the leads (the first lead 210 and the second lead 220) may be removed through a strip process.

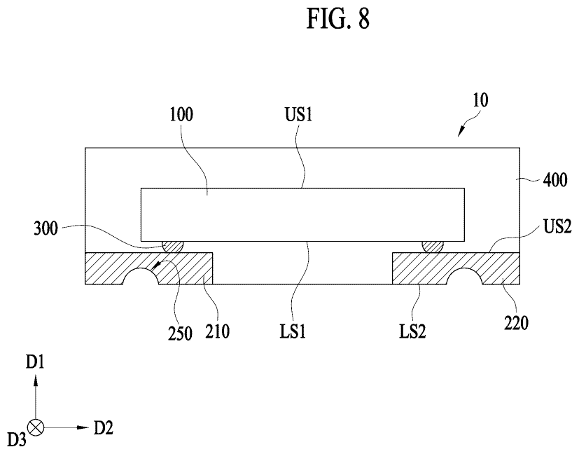

In some example embodiments, in operation S200 which is the molding process, at least a portion of the semiconductor chip 100 and at least a portion of the leads (the first lead 210 and the second lead 220) may be covered. In operation S200 which is the molding process, the bumps 300, which are positioned between the semiconductor chip 100 and the leads (the first lead 210 and the second lead 220), may also be covered. Specifically, the molding layer 400 may be disposed to cover the mounted semiconductor chip 100 and the each of the leads (the first lead 210 and the second lead 220) each of which has the recess 250. The injected molding layer 400 is heated at high temperature and hardened, and accordingly, at least the portion of the semiconductor chip 100 and at least the portion of the leads (the first lead 210 and the second lead 220) may be firmly covered. Here, as illustrated in FIG. 8 and as described above, the second surfaces LS2 of the leads (the first lead 210 and the second lead 220) may not be covered by the molding layer 400.

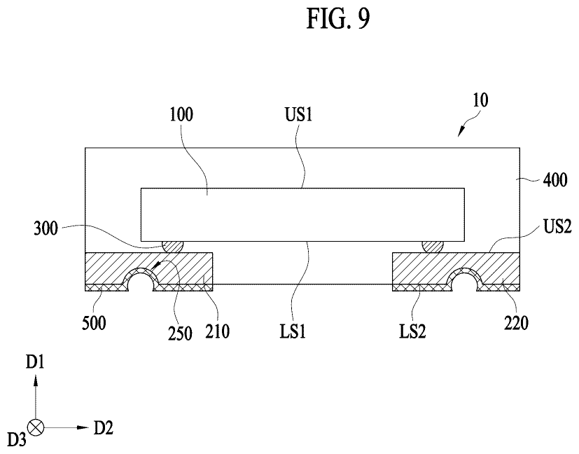

In some example embodiments, in operation S300 where a plating layer is formed, the plating layer 500 may be formed on the second surfaces LS2 of the leads (the first lead 210 and the second lead 220) that is exposed from (i.e., not covered by) the molding layer 400. For example, by performing an electroplating process to reduce and deposit tin (Sn) ions, as illustrated in FIG. 9, the plating layer 500 containing tin (Sn) may be formed on the second surface LS2 of the leads (the first lead 210 and the second lead 220). Here, it is apparent that through the operation S100 where recess 250 is formed, the plating layer 500 is also formed on the surface of the recess 250 formed on the second surfaces LS2 of the leads (the first lead 210 and the second lead 220). In some example embodiments, prior to forming the plating layer 500, the surfaces of the leads (the first lead 210 and the second lead 220) may be treated by polishing or the like so that the second surface LS2 may be fully exposed from the molding layer 400.

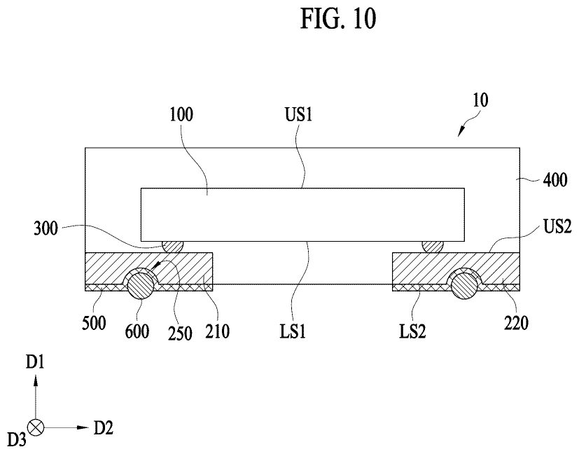

In some example embodiments, in operation S400 where the connecting structure body is attached, the connecting structure body 600 may be placed on the leads (the first lead 210 and the second lead 220). Specifically, the connecting structure body 600 may be placed in the recess 250 formed on the second surfaces LS2 of the leads (the first lead 210 and the second lead 220), and be reflow processed. Accordingly, as illustrated in FIG. 10, the connecting structure body 600 may be firmly attached to the plating layer 500 formed on the surface of the recess 250. Afterwards, through a cooling process, the connecting structure body 600 attached to the plating layer 500 formed on the recess 250 may be solidified.

In some example embodiments, at the panel level, multiple semiconductor packages 10 may be individually arranged. After going through the intermediate operations of the above described manufacturing method, the semiconductor package 10 may be manufactured by sawing each of the semiconductor packages 10. However, the present disclosure is not limited thereto. After going through the intermediate operations of the manufacturing method described above at the wafer level, the semiconductor package 10 described above may be manufactured by sawing. Further, any of the intermediate operations of the manufacturing method described above may be performed after the packages are individually sawed.

Below, a semiconductor package according to other embodiments is described. Except where otherwise stated, semiconductor packages described below have mostly the same or similar structure and function as the semiconductor package 10 described above (see FIGS. 1 to 4), and thus repetitive content is omitted. Further, in some example embodiments described below, the first lead and the second lead mostly have the same or similar structure and function, and thus example embodiments are described focused on the first lead.

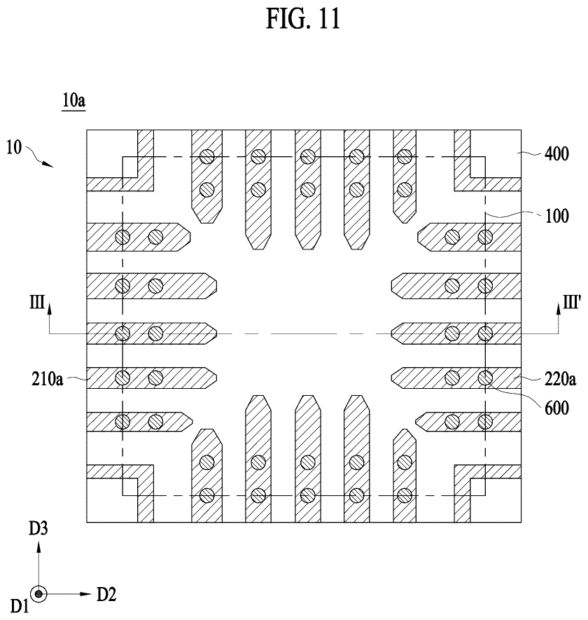

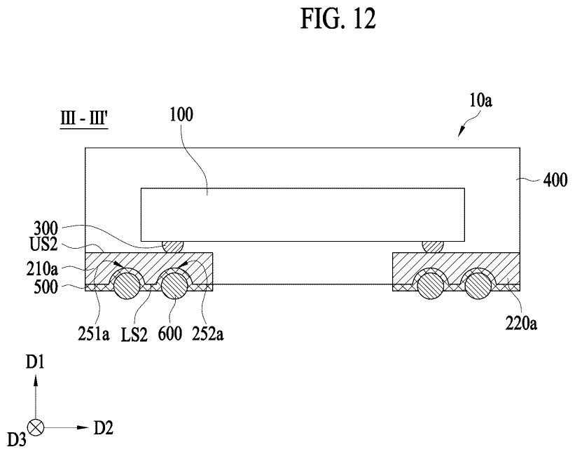

FIG. 11 is a bottom view schematically showing a semiconductor package according to an example embodiment. FIG. 12 is a drawing schematically showing a cross-section cut along line III-III′ of FIG. 11. In FIG. 11, the illustration of the plating layer 500 is omitted to help understanding.

Referring to FIGS. 11 and 12, a semiconductor package 10a may contain a first lead 210a and a second lead 220a. Further, a recess (a first recess 251a and a second recess 252a) may be formed in each of the first lead 210a and the second lead 220a. In some example embodiments, the first lead 210a may include the first recess 251a and the second recess 252a. The first recess 251a and the second recess 252a may be formed on the second surface LS2 of the first lead 210a. Further, the first recess 251a and the second recess 252a may be arranged at a certain distance from each other. The plating layer 500 may be formed on the surfaces of the first recess 251a and the second recess 252a, respectively. Further, according to some example embodiments, the connecting structure body 600 may be placed in each of the first recess 251a and the second recess 252a. Specifically, the connecting structure body 600 may be attached to the plating layer 500 formed on the surface of the first recess 251a, and the connecting structure body 600 may be attached to the plating layer 500 formed on the surface of the second recess 252a. A plurality of connecting structure bodies 600 may be connected to the first lead 210a for mounting. Accordingly, the semiconductor package 10 may be more firmly mounted on the package substrate 20 (see FIG. 4).

Unlike what is described above, any one lead may contain N recesses (where N is a natural number greater than or equal to 3). Further, the above described example embodiments are described in that a plurality of recesses formed in a single lead are spaced apart generally along the length of the lead. However, the plurality of recesses formed in a single lead may have various arrangements.

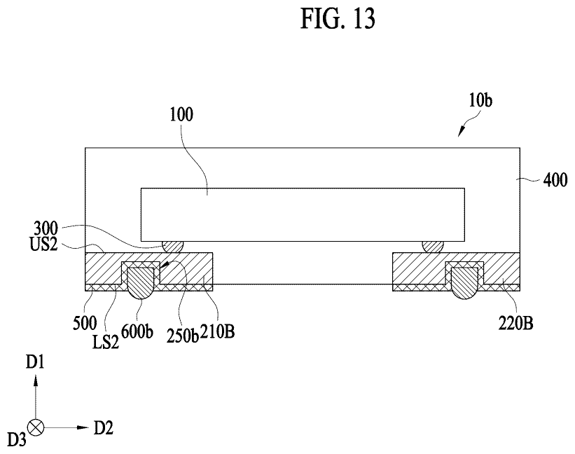

FIG. 13 is a cross-sectional view schematically showing a semiconductor package according to an example embodiment.

Referring to FIG. 13, a semiconductor package 10b may include a first lead 210b and a second lead 220b. Each of the first lead 210b and the second lead 220b may include a recess 250b. Specifically, the recess 250b may be formed on each of the second surface LS2 of the first lead 210b and the second surface LS2 of the second lead 220b. According to some example embodiments, the recess 250b may have a circular surface on the second surface LS2 of the first lead 210b. Further, the recess 250b may have a constant cross-sectional area regardless of the depth of indentation toward the first surface US2 of the first lead 210b. For example, the recess 250b may have a cylindrical shape. Accordingly, a connecting structure body 600b may be attached to the plating layer 500 formed on the surface of the recess 250b. According to the shape of the recess 250b described above, the upper portion of the connecting structure body 600b according to some example embodiments after reflow may have a generally cylindrical shape. The lower portion of the connecting structure body 600b may generally have a hemisphere shape.

Unlike the above example embodiments, the recess 250b may have a polygonal cross-section on the second surface LS2 of the leads (the first lead 210 and the second lead 220). For example, the recess 250b may have cross sections such as square, rectangular, rhombus, pentagon, and hexagon. Further, when the recess 250b has a polygonal cross section, the cross-sectional area of the recess 250b may generally decrease as it approaches the first surface US2 of the lead (the first lead 210 and the second lead 220). In contrast, the recess 250b may have a constant cross-sectional area regardless of the depth of the lead (the first lead 210 and the second lead 220).

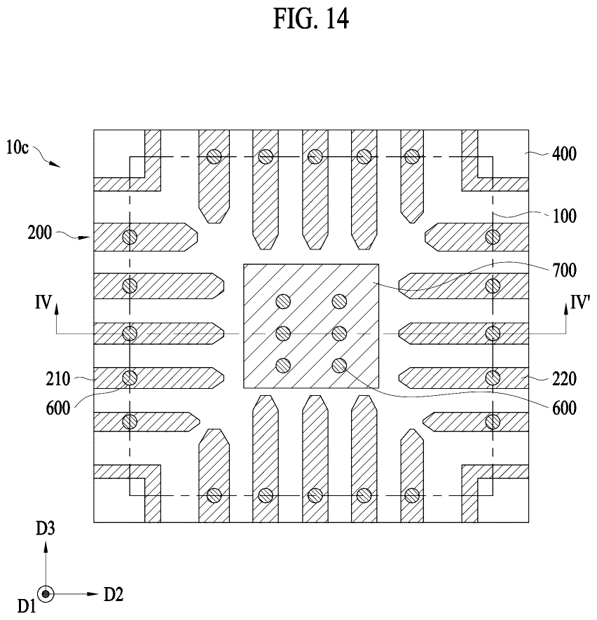

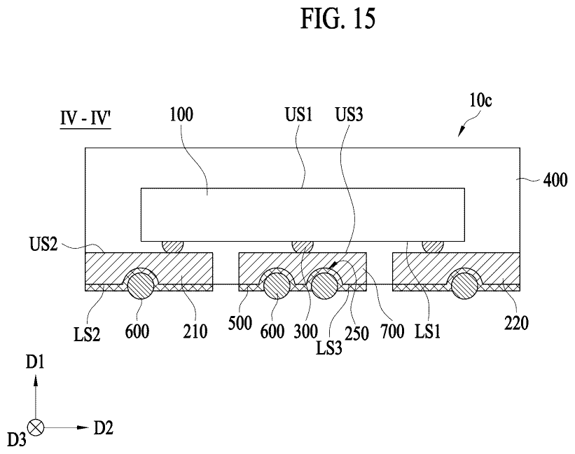

FIG. 14 is a bottom view schematically showing a semiconductor package according to an example embodiment. FIG. 15 is a drawing schematically showing a cross-section cut along line IV-IV′ of FIG. 14.

Referring to FIGS. 14 and 15, a semiconductor package 10c may further include a center pad 700. According to some example embodiments, the center pad 700 may contain metal material. Further, the center pad 700 may be a thermal pad that effectively dissipates heat generated from the semiconductor chip 100. Further, the center pad 700 may be a ground pad that contributes to improving electrical characteristics and reducing noise of the semiconductor package 10. Further, the center pad 700 may be a dummy pad placed for mechanical stability. However, the center pad 700 is not limited thereto. It is apparent that the center pad 700 may be modified into a pad that performs a variety of functions depending on design requirements.

According to some example embodiments, the center pad 700 may be placed in the center of the lead frame 200. Specifically, the center pad 700 may be placed in the space between the first lead 210 and the second lead 220. Further, the center pad 700 may be placed on the lower side of the semiconductor chip 100. For example, the center pad 700 may be arranged with the semiconductor chip 100 in the first direction D1, and the center pad 700 may be arranged with the first lead 210 and the second lead 220 in the second direction D2. Further, it is apparent that from the perspective of the leads arranged in the third direction D3, the center pad 700 may be arranged with leads in the third direction D3.

In some example embodiments, the center pad 700 may have a first surface US3 and a second surface LS3. With regard to the center pad 700, the first surface US3 and the second surface LS3 may be opposite surfaces. For example, the first surface US3 may be the top surface of the center pad 700, and the second surface LS3 may be the bottom side of the center pad 700. Further, the first surface US3 of the center pad 700 may face the second surface LS1 of the semiconductor chip 100. According to some example embodiments, the first surface US3 of the center pad 700 may be approximately horizontal to (e.g., coplanar with) the first surfaces US2 of the leads (the first lead 210 and the second lead 220). For example, the first surface US3 of the center pad 700 may share the same virtual plane as (e.g., coplanar with) the first surfaces US2 of the leads (the first lead 210 and the second lead 220). Further, the second surface LS3 of the center pad 700 may share the same virtual plane as (e.g., coplanar with) the second surfaces LS2 of the leads (the first lead 210 and the second lead 220).

According to some example embodiments, at least one bump 300 may be placed on the first surface US3 of the center pad 700. Accordingly, at least one bump 300 and the semiconductor chip 100 may be mounted on the center pad 700. For example, the center area of the semiconductor chip 100 may be mounted on the center pad 700, and the edge area of the semiconductor chip 100 may be mounted on leads (the first lead 210 and the second lead 220). Further, at least one recess 250 may be formed on the second surface LS3 of the center pad 700. The plating layer 500 may be formed on the surface of the recess 250 formed on the second surface LS3 of the center pad 700, and at least one connecting structure body 600 may be attached to the plating layer 500. According to some example embodiments described above, while satisfying various functional requirements, the recess 250 is also formed in the center pad 700 to further improve the structural stability of the semiconductor package 10.

The number and arrangement of the bump 300 placed on the center pad 700, the shape, the number and the arrangement of the recesses 250 formed on the second surface LS3 of the center pad 700, and the number and the arrangement of connecting structure bodies 600 attached to the center pad 700 are only mere example embodiments.

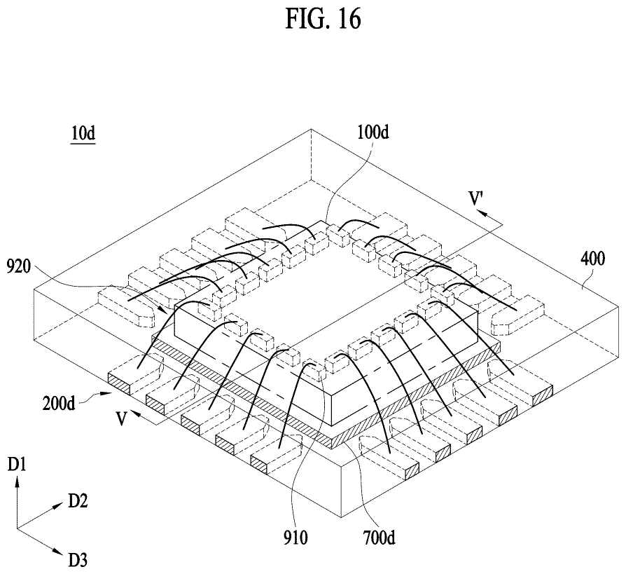

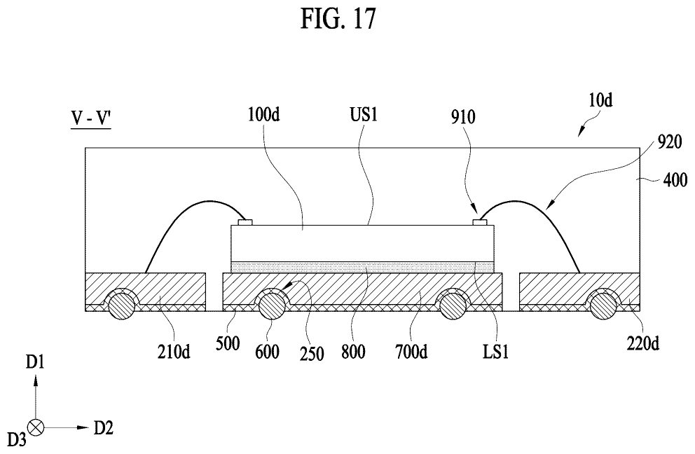

FIG. 16 is a perspective view schematically showing a semiconductor package according to an example embodiment. FIG. 17 is a drawing schematically showing a cross-section cut along line V-V′ of FIG. 16.

Referring to FIGS. 16 and 17, a semiconductor package 10d may further include a center pad 700d and wire 920. According to some example embodiments, a lead frame 200d may contain multiple leads. According to some example embodiments, the overall shape of the leads of the lead frame 200d may be formed identically or similarly to the leads of the aforementioned lead frame 200 (see FIG. 1). Specifically, the leads of the lead frame 200d may be formed to a generally shorter length than the leads of the aforementioned lead frame 200 (see FIG. 1). Further, the leads of the lead frame 200d may be arranged in a position that does not overlap with a semiconductor chip 100d in the first direction D1.

According to some example embodiments, the lead frame 200d may include a first lead 210d and a second lead 220d. The first lead 210d and the second lead 220d do not overlap with the semiconductor chip 100d in the first direction D1. The first lead 210d and the second lead 220d have mostly the same or similar structure and function as the first lead (the first lead 210, the first lead 210a and so on) (see FIG. 3, FIG. 12 and so on) and the second lead (the second lead 220, the second lead 220a and so on) (see FIG. 3, FIG. 12 and so on) described above, and thus, description with regard thereto is omitted.

According to some example embodiments, the center pad 700d may contain metal material. For example, the center pad 700d may be a thermal pad, a grounding pad, or a dummy pad. Further, the center pad 700d may be a spacer or a die paddle for structurally supporting and mounting the semiconductor chip 100d. However, the center pad 700d is not limited thereto. The center pad 700d may be transformed into a pad that performs various functions depending on design requirements.

According to some example embodiments, the center pad 700d may be placed in the center of the lead frame 200d. Specifically, the center pad 700d may be arranged with the semiconductor chip 100d in the first direction D1. For example, the center pad 700d may be placed on the lower side of the semiconductor chip 100d. Further, the center pad 700d may be spaced apart from the leads (the first lead 210d and the second lead 220d) along the second direction D2, and may be spaced along the third direction D3 from the perspective of the leads arranged in the third direction D3. According to some example embodiments, the center pad 700d may be bonded to the semiconductor chip 100d by an adhesive layer 800. For example, the adhesive layer 800 may include a die attach film (DAF) containing epoxy. However, the adhesive layer 800 is not limited thereto. The adhesive layer 800 may include a composite material of metal and polymer. The adhesive layer 800 may include a polymer material such as acrylic or silicone. The adhesive layer 800 may include an inorganic material such as glass or ceramic. According to some example embodiments, the center pad 700d may have the recess 250 formed on its lower surface identically or similarly to the center pad 700 described with reference to FIGS. 14 and 15. The connecting structure body 600 may be attached to the plating layer 500 formed on the surface of the recess 250. Accordingly, explanation of overlapping content is omitted.

According to some example embodiments, a bonding pad 910 may be formed on the first surface US1 of the semiconductor chip 100d. The wire 920 may be connected to the bonding pad 910. Specifically, one end of the wire 920 may be connected to the bonding pad 910, and the other end may be connected to a lead (the first lead 210d and the second lead 220d). Accordingly, the semiconductor chip 100d and the lead (the first lead 210d and the second lead 220d) may be electrically connected. Here, according to some example embodiments, the substrate of the semiconductor chip 100d may be positioned on the lower portion of the semiconductor chip 100d, and the interconnection structure of the semiconductor chip 100d may be located on the upper portion of the semiconductor chip 100d. Further, the interconnection structure of the semiconductor chip 100d may be electrically connected to the bonding pad 910. In some example embodiments, the bonding pad 910 and the wire 920 may be formed and provided in a number corresponding to the number of leads of the lead frame 200d. For example, the bonding pad 910 and leads may be connected one-to-one by the wire 920.

Some of the embodiments described above may be combined in various forms and reconfigured into further modified embodiments as long as they are not technically contradictory.

The above detailed description is illustrative of the present disclosure. Further, the above description illustrates and explains preferred example embodiments of the present disclosure, and the present disclosure may be used in various other combinations, modifications, and environments. For example, changes and modifications are possible in the scope of the present disclosure, the scope that is equivalent to the above description and/or the scope of technology or knowledge in the art. The above example embodiments describe the best state for implementing the technical idea of the present disclosure, and various modifications are also possible as required for specific application fields and uses of the present disclosure. Therefore, the detailed description of the present disclosure is not intended to limit the present disclosure to the described example embodiments. Further, the appended claims should be construed to include other example embodiments.

What is claimed is:

1. A semiconductor package comprising:
a first lead comprising a first surface and a second surface that is opposite to the first surface;
at least one semiconductor chip that is placed on the first surface of the first lead;
a connecting structure body that is connected to the first lead; and
a molding layer configured to cover the first lead and the semiconductor chip,
wherein the first lead comprises a recess that is formed on the second surface of the first lead,
wherein the connecting structure body is placed in the recess, and
wherein the semiconductor chip, the first lead, and the connecting structure body are electrically connected to each other.

2. The semiconductor package of claim 1, wherein a plating layer is formed on the second surface of the first lead including the recess.

3. The semiconductor package of claim 2, wherein the connecting structure body is attached to the plating layer where the recess is formed, and
the connecting structure body is a solder ball.

4. The semiconductor package of claim 3, wherein the plating layer comprises tin (Sn), and
wherein the connecting structure body comprises tin (Sn) and bismuth (Bi).

5. The semiconductor package of claim 1, wherein a bottom surface of the recess is located between the first surface of the first lead and the second surface of the first lead.

6. The semiconductor package of claim 1, wherein a thickness from the first surface of the first lead to a bottom surface of the recess is thinner than a thickness from the first surface of the first lead to the second surface of the first lead.

7. The semiconductor package of claim 1, wherein the recess comprises a circular cross-section on the second surface, and comprises a diameter that decreases toward the first surface of the first lead.

8. The semiconductor package of claim 1, wherein the recess comprises a cylindrical shape.

9. The semiconductor package of claim 1, wherein a plurality of recesses are formed on the first lead,
wherein the plurality of recesses formed on the first lead are spaced apart from each other.

10. The semiconductor package of claim 1, further comprising:
a second lead,
wherein the first lead is placed on one side of the semiconductor chip, and the second lead that is spaced apart from the first lead and placed on another side of the semiconductor chip,
wherein the semiconductor chip is placed on a first surface of the first lead and a first surface of the second lead,
wherein, between the first lead and the second lead, a center pad is placed comprising a first surface facing the semiconductor chip and a second surface that is opposite to the first surface,
wherein a recess is formed on a second surface of the second lead and a second surface of the center pad, and
wherein the connecting structure body is placed in each of the recesses.

11. The semiconductor package of claim 1, wherein the semiconductor chip is mounted on the first surface of the first lead by a bump connected to the first surface of the first lead.

12. The semiconductor package of claim 1, wherein the semiconductor chip is electrically connected to the first lead by a wire connected to the first lead.

13. The semiconductor package of claim 1, further comprising:
a plurality of leads, the plurality of leads includes at least the first lead and a second lead,
wherein, when viewed in a direction perpendicular to the first surface, the plurality of leads are spaced apart from each other on sides of the semiconductor chip in order to surround the semiconductor chip,
wherein recesses are formed on a second surface of each of the plurality of leads, and
wherein the connecting structure body is placed in each of the recesses.

14. A semiconductor package comprising:
a lead comprising a first surface and a second surface that is opposite to the first surface, and comprising a recess formed on the second surface;
a semiconductor chip that is mounted on the lead by a bump connected to the first surface; and
a connecting structure body that is connected with the second surface,
wherein the recess is formed toward the first surface from the second surface,
wherein the connecting structure body is placed in the recess, and
wherein the semiconductor chip, the lead, and the connecting structure body are electrically connected to each other.

15. The semiconductor package of claim 14, wherein a plating layer is formed on the second surface including the recess, and
wherein the connecting structure body is attached to the plating layer formed on the recess.

16. The semiconductor package of claim 15, wherein at least a portion of the plating layer comprises tin (Sn), and
wherein at least a portion of the connecting structure body comprises tin (Sn) and bismuth (Bi).

17. The semiconductor package of claim 14, wherein the recess comprises a cross-section that is circular, and comprises a diameter that decreases toward the first surface of the lead.

18. The semiconductor package of claim 14, wherein a vertical level from the second surface to the first surface is greater than a vertical level from the second surface to a bottom surface of the recess.

19. The semiconductor package of claim 14, wherein a plurality of recesses are formed in the lead,
wherein the plurality of recesses formed in the lead are spaced apart from each other on the second surface.

20. A semiconductor package comprising:
a first lead and a second lead each including a first surface and a second surface comprising a recess, the first lead and the second lead are spaced apart from each other;
a semiconductor chip mounted on both the first surface of the first lead and the first surface of the second lead;
a first bump disposed between and connected to the semiconductor chip and the first surface of the first lead and a second bump disposed between and connected to the semiconductor chip and the first surface of the second lead;
a plating layer, comprising tin (Sn), conformally disposed on the second surface and recess of each of the first lead and the second lead;
a first connecting structure body comprising tin (Sn) and bismuth (Bi), a portion of the first connecting structure body disposed in the recess of the first lead and is connected to and in contact with the plating layer;
a second connecting structure body comprising tin (Sn) and bismuth (Bi), a portion of the second connecting structure body disposed in the recess of the second lead and is connected to and in contact with the plating layer; and
a molding layer covering the first lead, the second lead, the semiconductor chip, the first bump, and the second bump.
